(19) United States
(12) Patent Application Publication
(10) Pub. No.: US 2007/0103993 A1
(43) Pub. Date: May 10, 2007

(54) Personal Portable Devices

(76) Inventors: Jeffrey R. Mount, Palm Harbor, FL (US); Justin A. Summer, Tierra Verde, FL (US)

Correspondence Address: NEIFELD IP LAW, PC, 4813-B EISENHOWER AVENUE, ALEXANDRIA, VA, 22304, US

(21) Appl. No.: 11/554,095

(22) Filed: Oct. 30, 2006

Related U.S. Application Data
(60) Provisional application No. 60/733,185, filed on Nov. 4, 2005.

(51) Int. Cl. G11C 7/10

(52) U.S. Cl. 365/189.05

(57) ABSTRACT

This application provides novel computer systems and method using novel personal portable consumer devices wherein the personal portable devices store, secure, communicate, and with or without an associated personal computer, process transaction data and incentive offers for the consumer.

### CROSS REFERENCE TO RELATED APPLICATIONS

This application claims priority to U.S. provisional application 60/733,185, filed Nov. 4, 2005, attorney reference PIP167MOUNP-US, titled “PERSONAL PORTABLE DEVICE; this application also claims priority to PCT application PCT/US06/31548, filed Aug. 11, 2006.” The contents of 60/733,185 and PCT/US06/31548 are incorporated herein by reference.

### FIELD OF THE INVENTION

This invention relates generally to novel computer systems using personal portable consumer devices therein for storing, securing, communicating, and processing transactions data.

### BACKGROUND OF THE INVENTION

U.S. Pat. No. 6,783,078 to Leaming teaches a smart card for operating in a USB mode and comprising a smart card body, an integrated circuit carried by said smart card body comprising a USB transceiver and a microprocessor connected to said USB. U.S. Pat. Nos. 6,738,873; 6,182,216; 6,315,195; 6,000,608. United States Pre Grant Patent Publication (PGP) 20040211835 to Toumemille teaches a smart card operable with a USB port or host; PGPs 20040225918; 20030221073; and 20010041991 also teach smart card, data storage, and USB concepts.

The foregoing disclosures lack concepts synergistically integrating consumer smart cards and networked computer systems with consumers product purchasing activities.

### SUMMARY OF THE INVENTION

This application discloses novel network computer systems (CSs) and portable person devices (PPDs) (such as in the shape of a USB stick, a smart cards, a cellular telephone, and similarly sized devices that can easily be carried by a person in one hand) that synergistically integrate for a consumer their product purchase planning and purchasing, product purchase history storage, personal identity storage, and provide data security and authorizations, and for marketers, manufacturers, and retailers, enable novel consumer specific incentive offer generation, storage, tracking, incentive credit and redemption tracking and auditing. The novel network CS also provides algorithms providing third party verification to consumers and vendors of consumer purchase transaction history accuracy and data vendor credit, thereby enabling consumers the ability to sell their purchase transaction history to a potential data vendor buyer verifying reliability and payment for both parties.

Further, the novel network CS enables a mechanism for a central CS to objectively associate purchase histories from different retail stores, each of which is tied to a different identifier for a single legal entity (person or artificial legal entity; herein after “person” or “consumer”) to the same person, enabling a more complete and accurate transaction history record for that person to be used for incentive offer targeting and demographics analysis. The mechanism is the data storage, and authorization and upload, from the consumer's PPD to the central CS of the CIDs and associated RIDs stored in the PPD in order to facilitate the consumer benefitting from purchase incentive offers.

The data verification inherent in the distributed data storage enables novel methods for consumers to sell their transaction data to data analyzers, while maintaining identity privacy.

Still further, the novel network CS enables a consumer to plan for shopping activities synergistically using their own prior transactions, and relying upon POS CS store algorithms to verify their intended purchases against their actual purchases.

Several other aspects and particular advantages therefore are describe below.

### BRIEF DESCRIPTION OF THE DRAWINGS

In the drawings and following description, the same figure reference numeral implies the same or very similar elements in the various figures.

FIG. 1 is a schematic system view of a novel network CS;

FIG. 2A is a top view of a personal portable device (PPD) 200;

FIG. 2B is a side view of the PPD 200 of FIG. 2A;

FIG. 2C is a front end view of the PPD 200 of FIG. 2A;

FIG. 3 is a schematic of field and data views of a portion of a data structure relating retail store (or a set of retail stores in the same retail store organization) identifications (RIDs) for corresponding retail store's point of sale (POS) CSs to Consumer's IDentifications (CIDs).

FIG. 4 is a schematic of field and data views of data structure 400 relating CID to transaction identification (TID) for transactions logged in association with the corresponding CID;

FIG. 5 is a schematic of field and data views of data structure 500 relating TIDs to the associated transaction data, including UPC, quantity (Q), retail price (P), and discount on price (D);

FIG. 6 is a schematic of field view of data structure 600 showing relationships between the portions of data structures shown in FIGS. 3-5;

FIG. 7 is a field view of data structure 700 specifying data fields defining an incentive offer;

FIG. 8 is a field view of an alternative data structure 800 specifying data fields defining an incentive offer;

FIG. 9 is a field view of data structure 900 specifying a redeemable value;

FIG. 10 is flow chart showing algorithm 1000 implemented in the personal device;

FIG. 11 is a flow chart showing algorithm 1100 implemented in the POS CS;

FIG. 12 is a flow chart showing algorithm 1200 implemented in the central CS;

FIG. 13 is a flow chart showing algorithm 1300 implemented in the auction CS; and

FIG. 14 is a flow chart showing algorithm 1400 implemented on the personal CS and the POS CS.

FIG. 15 is a schema in design view of data structure 1600 relating UPC code to product category, product category description, item description, and item image.

### DETAILED DESCRIPTION OF THE EMBODIMENTS

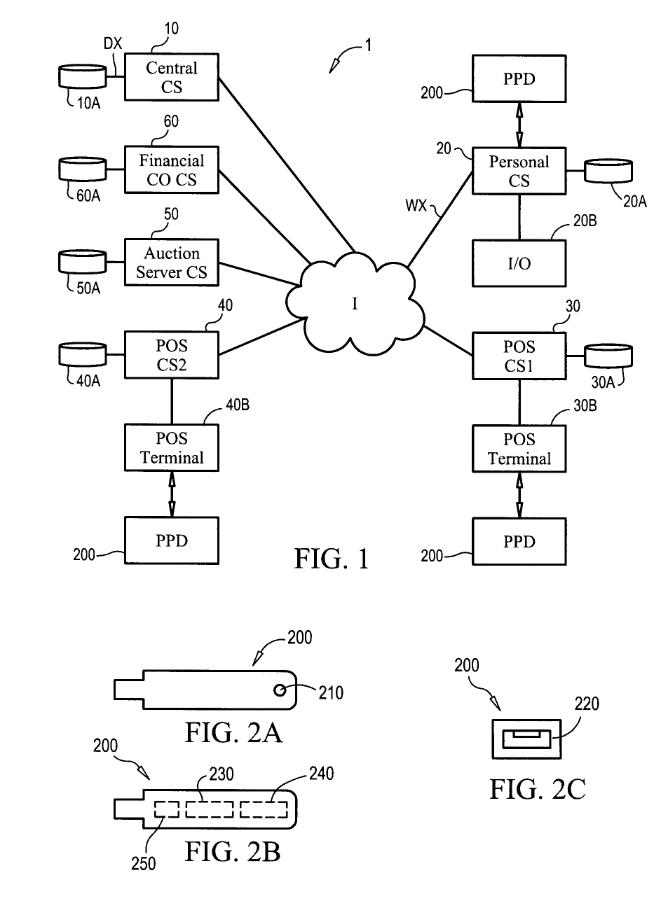

FIG. 1 shows network CS including central CS 10 and central CS database 10A, personal CS 20, personal CS database 20A, personal CS input output (I/O) 20B, POS CS1 30, POS CS1 database 30A, POS CS2 terminal 30B, POS CS2 40, POS CS2 database 40A, POS CS2 terminal 40B, auction server CS 50 and auction server database 50A, financial company CS 60 and financial company CS database 60A, network switching I, database communication control lines DX and network communication lines NX, and personal portable device (PPD) 200. Two headed arrow between PPD and CS or terminals indicate connect able bidirectional communication, either wired or wireless. PPD 200 is shown at various locations indicating its portability and interact ability with the POS CSs and the personal CS.

Each CS (10-60) includes a digital data processor, memory typically in the form of RAM and disk storage, I/O, and programming including an operating system and software. Each database represents data storage capability to which the corresponding CS controls read and write access via a DX line. Each CS is capable of communicating data to any other network addressable computer via network switching I. Network switching I may represent a packet switched network, such as the Internet or a private network, in which data is transported in packets using predetermined protocols, such as TCP/IP, that CSs 10-60 are preprogrammed to interpret. Alternatively, network switching may in part or in whole include real time session direct connection lines, such as plain old telephone lines (POTS) in lieu of packet switching.

Central CS 10 generally provides the functions of logging transaction and redemption data transmitted to it from a plurality of POS CSs, such POS CS1 and POS CS2, generating incentive offers targeted based upon a consumer's record, transmitting the incentive offers to other CSs of the network (POS CSs or PPDs or personal CS, or any combination thereof), and verifying redemption data it receives from the PPDs or personal CSs for a consumer against the consumer's transaction record of data received from POS CSs), and logging credit rewards for consumers accepting incentive offers.

Personal CS 20 provides some or all of the functions of (1) receiving a consumer's store transaction data from the consumers PPD 200, (2) analyzing that data using consumer centric analytics programs to define and communicate consumer information (for a consumer what food they might like to prepare, ingredients for recipes they might like to prepare, and lists of products they might like to purchase), (3) to print or display the results of the analysis, (4) to upload via network 1 to central CS 10 the consumer's transaction data, to (5) to upload the results of the analysis to PPD 200 and via network 1 to central CS 10. If should be noted that personal CS 20 has a more complete data set for the consumer than any POS CS because it associated purchases from all POS CSs with the consumer. Similarly, personal CS 20 has a more coherent data set for the consumer than central CS 10 because central CS 10 generally has no association with one another of transactions by the consumer from disparate POS CSs. Therefore, the analysis obtainable by personal CS 20 may be more accurate as to the consumer's preferences and purchasing patterns than any analysis obtainable by any POS CS or central CS.

POS CS1 30 and POS CS2 40 generally provide the functions of POS CS for a retail store in which the consumer uses in POS CS1 and POS CS2 different identifications in association with purchase transactions. Each of these CSs include a POS terminal for receiving transaction data for transactions by a consumer. Part of such transactions may include the POS terminal obtaining an identification for the consumer transacting at the POS. Embodiments of the novel methods herein include the POS terminal obtaining that identification from the consumer's PPD. The PPD may plug into a data port in a POS terminal modified to include such a port, or communicate with the POS terminal by exchanging wireless signals with the terminal. A wireless PPD may be activated to prompt for a RID or (and store lane identification in stores having more than one checkout lane) by a push button thereon, or by connection or magnetic switch implemented in the POS terminal.

Auction server CS 50 generally provides the functions of implementing in software sale for example via software implemented auctions by consumer's of their retail store data transaction records and purchase thereof by data analysis vendors.

Financial company CS 60 generally provides the functions of authorizing consumer credit on a transaction by transaction basis for POS CS and auction server transactions, and providing credit to the consumers for redemptions verified by for example the central CS.

PPD 200 generally provides the functions of storing a consumer's transaction data from transactions with a plurality of POS CSs, determining redemptions qualified by that transaction data, transmitting transaction data and redemption data to the central CS (perhaps via the personal CS), determining what stored data stored in PPD 200 a POS CS may access, and transmitting stored data when appropriately prompted to do so. The prompt should identify by RID either a POS CS, central CS 10, or personal CS 20. The prompt may include RIDs from several stores if from central CS 10 or personal CS 20. Alternatively, RIDs from central CS 10 or personal CS 20 may be associated with more than one, and preferably all other RIDs stored in PPD 200, such that a prompt reply including an RID from central CS 10 or personal CS 20 authorized PPD 200 to transmit all transaction data stored therein to the prompting CS.

FIGS. 2A-C show views of one embodiment of a PPD in the form of a digital processor and memory stick having a USB data connection plug, but no user I/O.

FIG. 2A shows aperture 210 enable the PPD to be connected for example to a key chain. 220 is the plug.

FIG. 2B shows in hashed lines internal elements of memory 230, optional CPU 240, and optional wireless transceiver unit 250.

FIG. 2C shows in end view plug region 220.

Alternatively, PPD 200 may be in the form of a smart card, that is, having the size and shape of conventional credit card. Such cards typically have dimension of about 5 centimeters by 10 centimeters by 1 millimeter. However, any dimension of a PPD that enable the device to be conveniently carried by a consumer are within the scope of the inventors conception, including PPDs included in a cell phone, PDA, or similar small portable memory storage device enabling data input and output to a CS having human I/O capabilities.

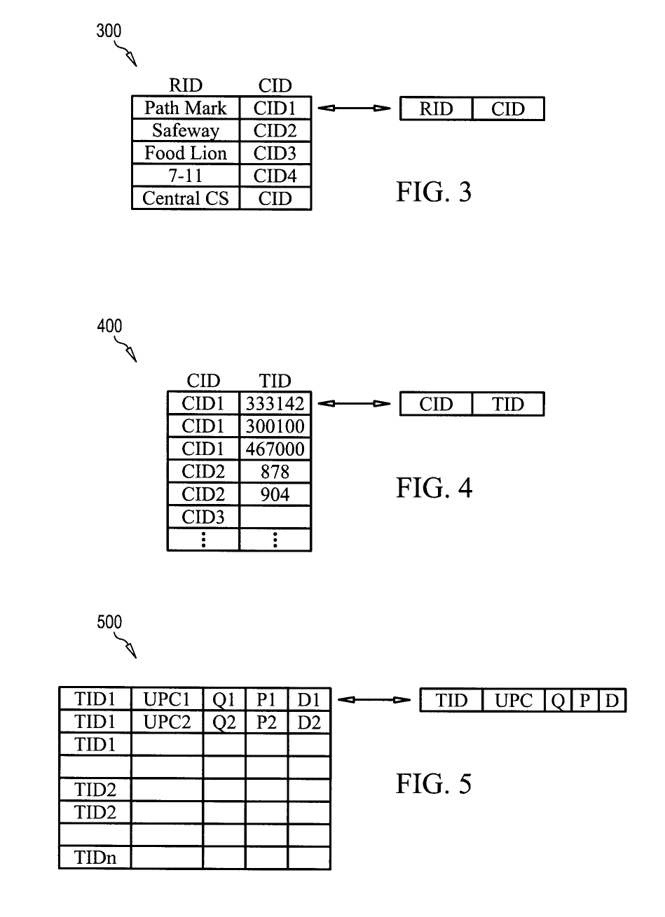

FIGS. 3-9 show portions of data structures useful in the PPD, the POS CSs, the personal CS, and the central CS, depending upon application, as specified below. In these figures, the transaction data for a consumer's transactions is redundantly stored in both the originating POS CS, the consumer's PPD, and the central CS. Each POS CS or retail organization's set of POS CSs store their transaction data for all transactions occurring in that store or set of stores. The consumer's PPD stores only the transaction data for transactions implementing that consumer's PPD. The central CS stores transaction data transmitted to it preferably from all associated POS CSs and all associated consumers' PPDs.

One important aspect of the novel network CS is that it enables both the PPD and the POS CS to record and store the same transaction data or incentive offers data, and to transmit that data or data derived therefrom to the central CS. As a result, the central CS can verify the existence and contents of the corresponding transactions and incentive offers status by comparing data it receives from the POS CS and the PPD, and can therefore also verify derivatives of that data, such as redemption amounts.

Another important aspect of the novel network CS is that, because the network system enables the central CS to validate derivative data, and redemption data is derivative data, the central CS can bypass the POS CS in communicating incentive offers and fulfilling redemptions. The central CS can communicate directly with the consumer via the consumer PC or PPD to both provide incentive offers storable on the consumer's PPD and validate transaction data and derivative data received from the PPD and consumer's CS against transaction data received from the POS CSs to confirm whether a redemption amount specified by a PPD's data transmission to the central CS, the POS CS, or the credit company CS is valid. Valid, in this sense, means that the consumer's purchases meet the terms of an offer provided to the consumer, and that the amount of value associated with the offer correspond to the amount of a redemption indicated by a consumer's PPD data transmission or consumer CS data transmission.

Actual low level data structure format naturally may vary from CS to CS and PPD. However, the high level relations shown in these figure between fields in what corresponds to data tables in relational database and what corresponds to primary and foreign keys between data tables in a relational database schema are important for implementations of the processes described herein below. While shown in a format conventional to relational databases, the data structures of FIGS. 3-9 are implement able in text based files, binary files, and markup language files, such as XML, files, so long as the data associations are preserved.

FIG. 3 shows a portion 300 of a data structure residing in the PPD, and preferably also residing in central CS 10 and not in a POS CSs 30, 40. Table 300 associates a set of Retail IDentifications (RIDs) with corresponding CIDs for a person possessing the PPD. It is important to note that the feature of transmitting this table data from the PPD to the central CS serves the novel function of enabling the central CS to associate with one another consumer data records for transaction data in different retail stores. Heretofore data records for the same consumer from different retailer were not associable with one another, in a central CS such as central CS 10, because no mechanism existed to make the association, and no mechanism existed to efficiently obtain consumer authorization for making the association. Most people use a different CID in different retail store chains, such as different credit card numbers, and retailer specific frequent shopper identifiers. Moreover, privacy concerns generally preclude central CS 10 from even determining whether an identical identifier (such as a portion of a credit card number) exists in different CID associated transaction records from different retail stores. A feature of the PPD and alternatively of the personal CS 20 is code providing to the consumer possessing PPD 200 and personal CS 20 a mechanism to authorize transmission of all of PPD 200's table 300 data to personal CS 20 and/or central CS 10. This feature may be implemented in code in PPD 200 responding to a prompt from personal CS 20 or central CS 10 (either via a wired connection or wireless connection, and possible transmitted via a wide area network) to authorize that transmission, and code storing the resulting transmission received by personal CS 20 or central CS 10 therein. Alternatively, PPD 200 may have a manually activated switch or button that initiates that data transmission.

Table 300 shows in field view on the right hand side associated fields RID and CID. Table 300 shows on the left hand side in table view associated pairs of data, each including a RID (in this case, a name of the retail company) and a CID (in this case exemplified by a sequence) including for example the RID “PathMark” for the retail store company named PathMark in association with a consumers CID used in Pathmark, “CID1”. The “CIDI” for example might be a 16 digit credit card number.

The bottom entry in table view is “Central CS” . . . “CID” indicating that a separate entry may exist for a master CID associated with the central CS.

Code implement able either in the PPD or in the personal CS may includes switches enabling the person possessing the PPD to specify what data records in the PPD each retailer may access, by specifying one or more RIDs for that retailer. Thus, a person may specify for example that each retailer's POS CS can read from their PPD only the data associated with transactions associated with that retailers, RID, a specified set of retailers RIDs, or all retailers' RIDs. PPD 200 may be structured to associate the RID “Central CS” with all retailer's RID, and the PPD may be structured to authorize a POS CS to access all data associated with the “Central CS” RID.

FIG. 4 shows a table 400 which is a portion of a data structure relating CID to transaction identification (TID) for transactions logged in association with the corresponding CID. Table 400 preferably resides in PPD 200, and also in central CS 10. Preferable, only that portion of data in data structure 400 obtained from POS CS1 resides in POS CS1. In other words, the PPD and central CS may store in table 400 TIDs from multiple POS CSs, and each POS CS preferably stores only the CID to TID correspondence for transactions that occurred in that POS CS.

Each TID is generated by a POS CS and TIDs generated by a POS CS are generally each unique. The right hand side field view of 400 shows fields for CID and TID associated with one another. The left hand side of 400 shows data pairs, such as CIDI and TID 33142. Note that the TIDs are unique whereas the CIDs appearing in 400 are not unique since each CID will appear for all transaction in a POS CS in which that CID was presented by the consumer.

FIG. 5 shows a table 500 of a portion of a data structure relating TIDs to associated transaction data. The table associations of table 500 and transaction data resulting from for example POS CS1 preferably reside in POS CS1, PPD 200, and central CS 10. However, POS CS1 preferably stores in addition all data records for all of its customers, PPD 200 stores data records for only the person possessing PPD 200, and central CS 10 stores data records for all consumers having PPDs and from all POS CSs that transmit transaction data to central CS 10. Thus, importantly, the transaction table data structure in each of the three network component may be the same, but the actually data stored in each transaction table in the various network components differs from one another.

Herein, UPC is defined to refer generically to any specification used to identify products, including the original UPC specification and subsequent specifications derived therefrom.

As shown in the field view on the right hand side of FIG. 5, the associated item identification, quantity, price, and discount transaction data, including UPC, quantity (Q), retail price (P), and discount on price (D). The left hand side of FIG. 5 shows in table view actual associated data record field values, such as TID1, UPC1, Q1, P1, and D1.

A one to many relationship is indicated by a connecting line that branches to multiple lines where it connect to the field of the table having many records with the corresponding data element.

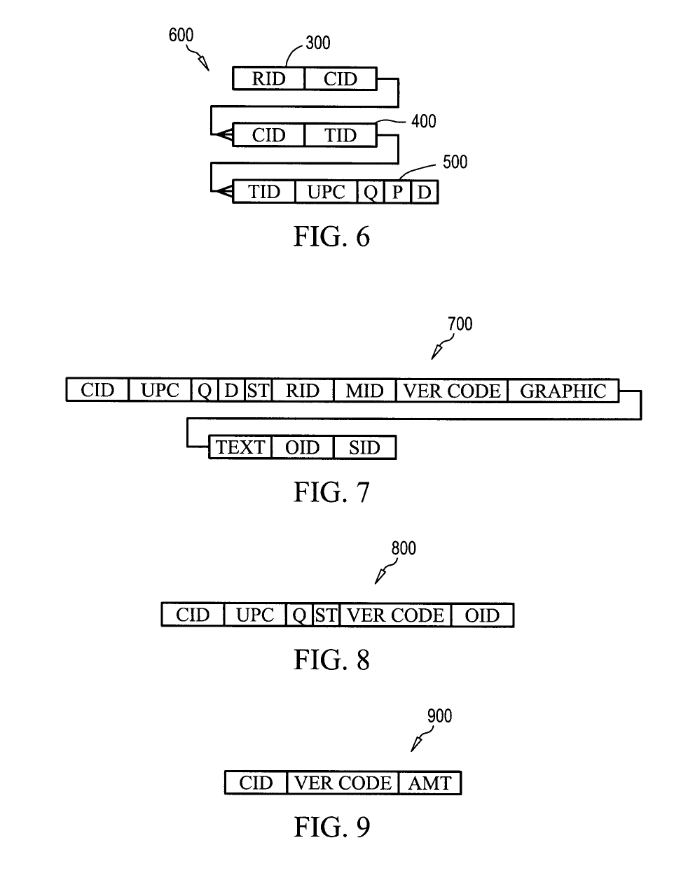

FIG. 6 shows in field view primary key to foreign key types of relationships between the portions of data structures shown in FIGS. 3-5. FIG. 5 shows that table 300 key CID has a one to many relationship with table 400's CID field; that table 400's TID field has a one to many relationship with table 500's TID field. Thus, FIGS. 3-6 summarize a preferred embodiment of the transaction data storage amongst the PPDs (and alternatively or additionally the corresponding personal CSs), the PS CSs and the central CS of the novel network CS.

An incentive offer is a conditional contract, in which specific actions are required by a consumer to fulfill the contract in order to be entitled to the reward offered therefore. Rewards specified in incentive offers specifying purchase of an item of a product are usually paid for by manufacturers or retailers.

FIG. 7 is a field view of a portion of a data structure 700 specifying data fields defining an incentive offer. These fields include CID, UPC, Q for quantity, D for discount amount (the reward), ST for status of the offer (for example, outstanding, fulfilled but not redeemed, fulfilled and redeemed, no longer valid), RID, MID for manufacturer identification, VER CODE for verification code, Graphics for a pointer to an associated graphics file, text for text associated with the incentive offer, and OID for offer identification, such as a unique identifier for each incentive offer, and SID for a retail store or POS CS identification indicating where purchase occurred that accepted the incentive offer. The CID field specifies a consumer identification. The UPC field specifies at least one product item identifier code (or a set of product item identifier codes) that must exist in a purchase for the purchase to meet the terms of the incentive offer and thereby accept the offer. The Q field stores data indicating a quantity of product items having the UPC field data that are required for a purchase to accept the incentive offer. The D field specifies any value amount for the consumer accepting the incentive offer. The ST specifies the status of the incentive offer, such as offer not accepted, offer accepted, offer no longer valid (out of date), or unknown.

In all embodiments, the PPD optionally stores either or both of the corresponding consumer's transaction data and incentive offers data. Storing in the PPD the POS CSs transaction data and transmitting that data to the central CS enables the central CS to double check the data it receives from the PPD against the data it receives from the POS CSs and to determine incentive offers status for the CIDs associated with the PPD.

In one embodiment, a data structure having some or all of the fields shown in FIG. 7 exists in each of the PPD, POS CSs, and the central CS.

Preferably, central CS 10 generates incentive offers data specific to each CID, central CS database 10A stores data structure 700 and therein stores the incentive offers data specific to each CID. Regarding generating incentive offers specific to each CID, central CS 10 receives transaction data from the POS CSs, determines therefrom when a CID and from predetermined incentive offer criteria what specific incentives offers to associate with each CID, and updates an account associated with that CID by associating therewith the specific incentive offers.

The predetermined incentive offer criteria may specify both prerequisites for associating any incentive offer with a CID, the requirements for accepting the offer (such as purchase of one or more specified product items), and the reward for accepting the offer (such as a reduction in the price of the item at time of purchase, coupon for future purchase, or rebate form for credit from a packaged goods manufacturer).

Alternatively, and in addition to central CS 10 generating and storing data in a data structure 700, any of the POS CS may generate and store incentive offer data in a data structure 700. Preferably, all such incentive offer records (incentive offer record referring to data defining one incentive offer) are transmitting to central CS 10 and stored in central CS database 10A.

In some embodiments, data structure 700 exists in the POS CS, the central CS, and the PPD. In these embodiments, central CS 10 may obtain the status of all offers associated with the CID for a POS CS from both the PPD and the retail store's POS CS in which that CID is stored, and also obtain the underlying transaction data from the retail store's POS CS or both the retail store's POS CS and the PPD in which that CID is stored. Central CS 10 can verify the transaction data from the POS CS against the transaction data from the PPD for the same CID to confirm accuracy and prevent fraud. Central CS 10 can also verify the incentive offer data in the data structure 700 received from the POS CS and the PPD for the same CID against one another to confirm accuracy and prevent fraud.

In some embodiments, data structure 700 does not exist in the POS CS, does exist in the central CS, and does exist in the PPD. In these embodiments, central CS 10 receives from the PPD incentive offer records and receives from the (or several) POS CS(s) transaction data for the CIDs associated with the PPD, and verifies the corresponding consumer's entitlement to rewards by independently verifying from the corresponding transaction data the reward status (ST field) in the data for data structure 700 received from the PPD.

Storing in the PPD the incentive offers data enables, transmitting that data to the central CS, and particularly the offer status data, and the central CS independently receiving from the corresponding POS CSs transaction data from which the incentive offers status data is derived, enables the central CS to verify the rewards status in the PPD against actual transaction data. Moreover, storing in the PPD the incentive offers data enables implementing a system in which the POS CS does not need to store incentive offers data. Specifically, central CS 10 can determine from each PPD the status of associated incentive offers and determine solely from transaction data received from the corresponding POS CSs whether the status of the associated incentive offers is valid.

Moreover, storing incentive offers data on PPDs and central CS 10, as opposed to storing the incentive offers data in POS CSs and central CS 10, provides an additional advantage enabling identifying all consumer purchases that are acceptances of incentive offers. To understand why, compare against a prior system in which only the POS CS for a consumer's “home store” (store in which the consumer most often purchases goods of a retail chain using the same CID) incentive offers data associated with that CID and the POS CSs of the consumer's non home stores do not store incentive offers data associated with that CID. The prior art system would not recognize the consumer's purchases in non home stores as accepting incentive offers for the consumer. In contrast, storing the incentive offers data in the PPD ensures that the consumer is credited for accepting all incentive offers available to that consumer since all such offers are stored on the PPD and travel with the consumer to each retail store.

FIG. 8 shows an alternative data structure 800 specifying data fields defining an incentive offer. The FIG. 8 fields are identical to those shown in FIG. 7. FIG. 8 illustrates that not all data fields shown in FIG. 7 are necessary to implement various embodiments.

In embodiments, PPD 200 and POS CSs contain different incentive offers data structures, such as PPD 200 containing data structure 700 and POS CS containing data structure 800, or vice versa. For example, it may be more efficient for only the PPDs to store information, such as text and graphics, to reduce the data storage load on the POS CS. This also enables the consumer via use of an I/O device like personal CS 20 to review the description of incentive offers to plan shopping trips. Alternatively, it may be more efficient to store a single instance of each text and graphics datum solely on the POS CSs since that would reduce the data transmission load on the POS CS in sending the same text and graphics datum to each PPD having a corresponding incentive offers data record.

In some embodiments, an identical data structure 700 may reside on both the POS CSs and the PPD, and certain fields, such as the text and graphics fields, may be initially populated with data in only one or the other. Software resident in either the PPD or the personal CS enables text and graphics fields not populated with data in the PPD but for which an incentive offer exists to be downloaded from the central CS, a POS CS, or sponsor of the incentive offer (such as a manufacturer)'s CS, upon prompt from the PPD or the personal CS. For example, if a consumer runs an analytics program, that program may prompt for download of missing text and graphics data, as needed, for display in a resulting analysis. The ability to download, only as needed, incentive offers data reduces the data transmission load on the network CS.

FIG. 9 shows a data structure 900 specifying a redeemable value. Data structure 900 may reside on any of the CSs described herein. Data structure 900 is useful in implementing rewards to consumers that are not provided during a transaction at a POS. That is, data structure 900 is useful for crediting consumer's accounts. In one embodiment, data structure 900 resides on central CS database 10A. In another embodiment, data structure 900 resides on both central CS database 10A and personal CS database 20A. In another embodiment, data structure 900 resides on financial company CS 60 and optionally one or both of central CS database 10A and personal CS database 20A.

Implementing credits to a data record for a consumer in data structure 900, generally proceeds as follows.

In embodiments in which PPD 200 stores incentive offers data, such as in data structure 700, PPD 200 runs code that maintains a running total of reward entitled to the various CIDs associated therewith.

Central CS 10 verifies a corresponding CID's entitlement to a reward for accepting an incentive offer. It does so by comparing data obtained from POS CSs and a PPD for one or more CIDs associated with the PPD, as previously described.

Upon verifying rewards for monetary value due to a consumer, central CS either runs code to update a running total amount of credit due to that consumer, transmits the verified amount in association with a CID to financial company CS 60, or both. Central CS 10 tracks the amount owed by sponsors (those who have agreed to pay for the accepted incentive offers) resulting from accepted incentive offers, the amount owed to the financial company CS (or financial companies CSs), based upon verified rewards, to maintain and balance accounts.

Consumer's may be able to review the credit specified by data in the data structure 700 on their PPD against the corresponding account information stored in financial company CS 60 or central CS 10, to verify proper crediting.

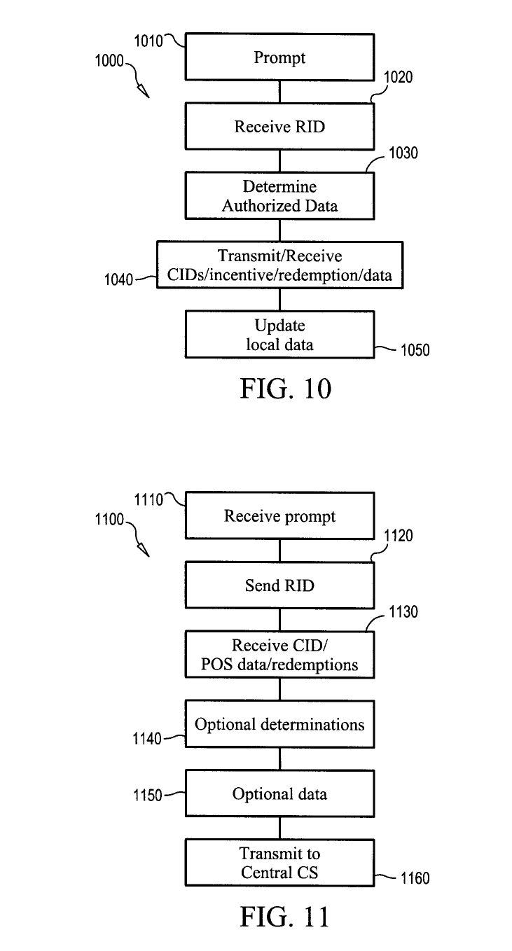

FIG. 10 is a flow chart showing algorithm 1000 implemented primarily in the PPD 200.

In step 1010, PPD 200 prompts for a retail store or retail store lane identification (RID; RLID). This prompt may be initiated by a signal in PPD 200 generated when it is mechanically or electrically connected to a physical port of a retail store's POS CS, such as a port at a POS. Alternatively, this prompt may periodically wirelessly broadcast from the PPD. Alternatively this prompt may be initiated by a prior prompt from a wireless node of the POS CS thereby identifying to the PPD proximity to a corresponding POS CS.

In step 1020, PPD 200 receives the RID from the POS CS with which the consumer possessing PPD 200 is transacting.

In step 1030, PPD 200 determines what data from PPD 200 it is authorized to transmit to the POS CS based upon authorization data stored in PPD 200 in association with the received RID.

In step 1040, PPD 200 and the POS CS exchange data, including data relating to a transaction. This step includes POS CS reading transaction data from a POS terminal with which a CID corresponding with the PPD is currently associated. For example, the consumer may provide to a scanner of the POS terminal a card with a bar code or magnetically recorded CID, the PPD may transmit to the POS CS a CID stored therein. The POS CS also reads product item transaction data corresponding to UPCs for product the consumer is currently purchasing. The POS CS may also read selected incentive offers data and redemption data from PPD 200. The selected data is data PPD 200 authorized for transmission to the identified POS CS in step 1030. For example, there may be retail store specific incentive offers, identified by OID or RID, inapplicable to the store associated with the POS CS with which the consumer is currently transacting; PPD 200 may not authorize for transmission to this POS CS data defining such incentive offers.

In one embodiment, PPD 200 transmit data originating in its data structure 700, for incentive offers to the consumer possessing PPD 200, to the POS CS. The POS CS determines from that data whether current transaction data constitutes acceptance by the consumer of any outstanding incentive offers available to that consumer, and responds to that determination. Alternatively, the POS CS also determines whether current and past transaction data associated with that CID constitutes acceptance by the consumer of any outstanding incentive offers available to that consumer, and responds to that determination. The POS CS may respond based upon the determination and terms of the incentive offer by providing a reduction on the current purchase price, generating a new incentive offer for the consumer and transmitting that to one or both of PPD 200 and central CS 10, or forwarding data defining a credit for the consumer accepting the incentive offer in association with the corresponding CID to central CS 10.

In some embodiments, the POS CS transmits the transaction data for the current transaction to PPD 200, and PPD 200 stores that data in its instances of data structures 300-500. Preferably, in these embodiments, the POS CS also specifies a TID for the current transaction.

In some embodiments, PPD 200 is configurable to specify whether it should transmit transaction data stored therein for CIDs other than the CID recognized by the POS CS involved in a current transaction. In these embodiments, when PPD 200 is in fact configured to transmit to the POS CS with which it is currently involved in a transaction, transaction data associated with other CIDS stored in the PPD, the POS CS may determined from that increased data set incentive offers data for which the consumer's transactions constitute an acceptance of incentive offers not yet specified with a status of accepted, and update status of those offers to accepted.

In step 1050, PPD 200 updates data stored therein (1) based upon data received from the POS CS (including RID, TID, and transaction data) and (2) optionally based upon code implemented in PPD 200 for determining incentive offers accepted based upon the current transaction data and optionally prior transactions' data.

FIG. 11 is a flow chart showing algorithm 1100 implemented primarily in the POS CS.

In step 1110, the POS CS receives a prompt for an RID and optionally for a POS lane identification.

In step 1120, the POS CS transmit at least an RID to PPD 200.

In step 1130, POS CS receives a CID for a transaction, and also receives transaction, and optionally incentive offer and redemption data, as discussed for FIG. 10.

In step 1140, POS CS optionally determines whether to transmit or receive from PPD 200 other data, such as marketing survey results and questionnaires, current conditions alerts, such as local traffic, weather, emergency conditions, product recalls, and missing or wanted person information.

In step 1150, the POS CS transmits or receives the optional data identified in step 1140.

In step 1160, the POS CS transmits data, including at least one of transaction data or incentive offers data associated with the CID to central CS 10. This data may be transmitted in batch mode along with a large number of transactions logged in the POS CS. Alternatively, part or all of the data for a transaction may be transmitted from the POS CS to the central CS during the transaction.

In some embodiments, central CS 10 receives during a transaction CID data and transmits back to the POS via the POS CS new incentive offer data or status changes of existing incentive offers data compared to offers previously transmitted to the POS CS or PPD. That transmission during a transaction may prevent double crediting of certain incentive offers to the account associated with a CID, and it also may enable the consumer possessing PPD 200 qualify during the transaction for incentive offers not previously stored in POS CS of PPD 200 at the beginning of the transaction.

In some embodiments, central CS 10 receives a CID during a transaction and transmits back to the POS CS a credit amount due to the consumer associated with that CID. The POS CS may then reduce the charge of the current transaction to the consumer by part or all of that credit amount due to the consumer. The credit amount may exist, for example, due to the consumer mailing in paper manufacturer rebate forms, due to verification that the consumer's prior transactions in the current POS CS or other POS CSs accepted incentive offers to the corresponding consumer. Thus, in some embodiments, the consumer may obtain credit in the form of a deduction on their current transaction cost, regardless of where the transactions resulting in the credit occurred. In some embodiments, the consumer may be given a choice at the POS to apply any such credit to reduce the cost for the current transaction, or retain the credit.

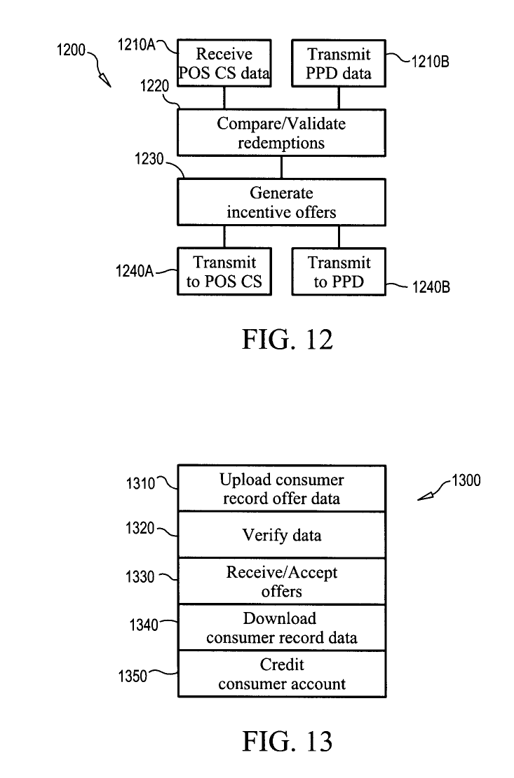

FIG. 12 is a flow chart showing algorithm 1200 implemented in the central CS.

In step 1210A, central CS 10 receives from one or more POS CSs transaction data for transactions of consumers in those stores. The transaction data may includes the data field specified in data structure 600 of FIG. 6 (RID, CID, TID, UPC, Q, P, and D) and also optionally store identification, store POS lane identification, data and time of purchase information, payment type information, etc.

In step 1210B, central CS 10 receives from PPD 200s one or both of transaction data for the fields shown in data structure 600 and any of the aforementioned optional data. However, data received from any PPD 200 includes only transactions associated with a CID stored in that PPD. Step 1210B includes receipt of data via personal CS 20. Preferably, PPD and the POS CS use identical data structures to reduce complications in importing and comparing that data at central CS database 10A.

In step 1220, central CS 10 validates transaction data by comparing the transaction data and incentive offers data received from the POS CSs and the PPDs against one another to generate validation results. Central CS 10 uses the validation results to determine whether to credit a consumer for accepting an incentive offer. Central CS 10 may then update an account for that consumer, and may transmit the validated amount in association with a CID for the consumer to financial company CS 60 wherein financial account data for the consumer is stored.

In step 1230, central CS 10 generates incentive offers for a specific consumer. It does so by determining whether the consumer's prior purchase history meets criteria specified by sponsors. The sponsors generally are retailers (companies owning retail stores) and manufacturers (companies whose products are sold in retailer's stores). Many of the incentive programs depend upon patterns of purchase by a consumer over a recent prior time period, such as a preceding week, month, or 6 months. One benefit of the network CS including PPDs 200 is that PPDs 200 provide to central CS 200 an aggregate of purchase data for a consumer's purchases associated with a variety of CIDS. The aggregation of this data provides for a more complete transaction data record for the consumer and therefore a more accurate implementation of a sponsor's criteria.

The aforementioned aggregation also enables central CS 10 to actually quantitatively determine a consumer's loyalty to a particular retail store, retail store chain, and to do so by product category and product. The actual quantitative determination of loyalty by retail store, retail store chain, product category, and product, enables a retail store to target consumers for purchase incentives based upon areas of lack of loyalty, areas in which the consumer or a group of consumers tend to not purchase from a particular retail store. For example, if a fraction of a group of consumers or an individual consumer's purchases in a specified retail store of nine product categories is seventy five and of a tenth category is at fifteen percent, the retailer may act to improve its product offerings in the tenth category, offer an incentive for the consumers or the one consumer to purchase in the tenth category, generally reduce the prices for products in the tenth category.

In step 1240A, central CS 10 transmits data back to the POS CSs. This data may consist of incentive offers data, either for a CID engaged in a currently in progress transaction or for CIDs not currently engaged in a transaction. The POS CS may store data for CIDs not currently engaged in a transaction, for use when those CIDs are identified in a transaction. Central CS 10 may also transmit to POS CSs credit amounts in association with a CID due to a consumer identified by that CID.

In step 1240B, central CS 10 transmits data to PPDs 200. This data may include incentive offers data for incentive offers specific to a variety of CIDs for the consumer stored in the consumer's PPD, incentive offers generic to all CIDs for the consumer stored in the consumer's PPD. This data may also include specification of a credit balance or new credits associated with the consumer's transactions as verified by central CS 10, exceptions, such as when verification failed, and depletions of credits, such as depletion due to use of a credit to reduce an out of pocket cost to the consumer of a prior transaction. In addition, the credit data may include a transfer specification, wherein central CS 10 specifies to the consumer possessing the CID and an account with the financial company owning financial company CS 60 a transfer of credit from central CS 10 to the consumer's account with financial company.

FIG. 13 is a flow chart showing algorithm 1300 implemented in auction CS 50.

In step 1310, a consumer uploads or agrees to have uploaded on their behalf, transaction data verifiable by central CS 10 as associated with the consumer's transactions. Optionally, the consumer may specify data from which of its CIDs to have uploaded, data from which categories of purchase to have uploaded, and data from which time periods to have uploaded.

In step 1320, central CS 10 verifies accuracy of that data against its records for the corresponding CIDs.

In one embodiment, the consumer authorizes central CS 10 to upload the consumer's data stored in central CS database 10A. This data has already been verified as accurate, since it has been received, or compared with, transaction data for that consumer transmitted from one or more POS CSs.

In one embodiment, the consumer uploads data from his PPD. In this embodiment, central CS 10 may be used to verify the data for auction CS 50. The upload may be initially to central CS 10, and after verification, to auction CS 50. The upload may be directly to auction CS 50, which then transmits the data to central CS 10 for verification, and awaits a verification signal from central CS 10.

In step 1330, after a consumer's data is verified, the consumer may accept from a purchase an offer to purchase from any consumer verified data for specified categories of products, retail stores, and time periods. Alternatively, the consumer may offer that data for specified categories of products, retail stores, and time periods for sale to any purchaser, and the purchase may interact with the web site to purchase the data.

In step 1340, a purchaser downloads one or more purchased consumer data records.

In step 1350, auction server 50 credits a consumer seller's account and debits a purchaser's account for the transaction involving sale of the consumer's transaction data.

Benefits of use of a PPD to implement sale of a consumer's transaction data is that the data is objectively verifiable, does not require release of consumer identity information (CID or consumer name or actual street address), and enables a consumer to sell that data for value.

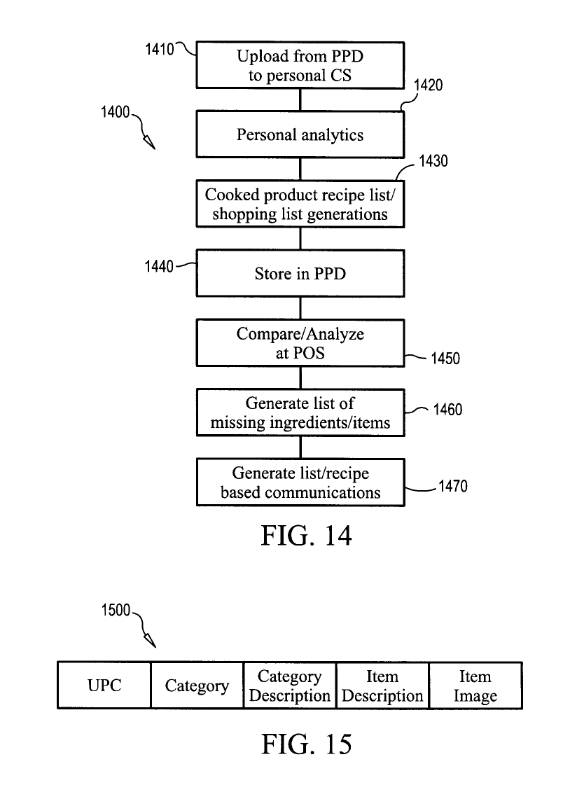

FIG. 14 is a flow chart showing an algorithm 1400 implemented on either PPD 202, personal CS 20, or both PPD 200, and a POS CS, relating to a consumer's analysis of their own transaction data, generation of recipes, and identification by POS CSs of transaction missing specified recipe items.

In step 1410, PPD 200 uploads transaction data to personal CS 20.

In step 1420, personal CS 20 runs transaction data analytics code having various goals. The code may determine from the data products that the consumer could cook using the product items purchased, specify recipe ingredients therefore, generate a shopping list of items the consumer often uses, estimate usage rates of items purchase to include in a shopping list product items the consumer will likely use up prior to the consumer's anticipated next shopping visit. This software optionally could reside in the consumer's PPD or at central CS 10.

In step 1430, in any event, recipe ingredient lists, cooked products obtained from recipes, and shopping lists resulting from the analysis and an additional consumer specification are stored in PPD 200. Optionally, when a consumer enters a retail store, the consumer may interact with the POS CS for that store to obtain a human readable copy of their lists stored in the PPD, and, importantly, the POS CS may also store that information. Additionally, the consumer may interact with the POS CS to obtain a machine readable identifier of those lists, such as a bar code printed on paper. If the POS CS generates a bar code, it also stores in association with that machine readable printout (bar code), data identifying the lists received from the PPD. Optionally, the POS CS also stores in association with the machine readable printout the consumer's CID.

In step 1450, the consumer enters into a transaction at a POS of the POS CS. The POS CS reads UPC data specifying products in the consumers purchases. The POS CS may identify exceptions to the consumer shopping list, to the consumer's lists of ingredients, or to ingredients necessary to prepare a cooked product identified in the consumer's lists. The exceptions identify items in the consumer shopping list, to the consumer's lists of ingredients, or to ingredients necessary to prepare a cooked product identified in the consumer's lists, that do not exist in the consumer's products being purchased as identified at the POS. Instead of using the consumer's PPD at the POS CS to identify the consumer's lists, the consumer may instead present the bar code for scanning at the POS so that the POS CS can identify the lists associated with the customer's CID.

In step 1460, the POS CS generates a list of missing product items based upon the exceptions.

In step 1470, the POS CS communicates that list of missing product items based upon the exceptions to the consumer.

A benefit of the method of algorithm 1400 is that it enables the consumer to identify items the consumer may need in the near future prior to the consumer leaving the store. Thereby, enabling the consumer to avoid an additional trip to store to purchase those items.

FIG. 15 shows data structure 1500 which includes a table design view associating fields for UPC, Category, Category description, item description, and item image, with one another. The UPC field stored product identifiers. The category field stores category identifiers. The category description field stores textual description of categories. The item description stores a text description of the item having the UPC code. The item image field stores an image of the item having the UPC code. An example of one record in data structure 1500 might be, 12345678910, 540, 16 ounce ground coffee, Maxwell House 16 ounce coffee can, [image of Maxwell House 16 ounce coffee can]. In this example, 12345678910 represents the UPC for Maxwell House 16 ounce coffee can, and 540 represents the category for 16 ounce ground coffee products.

Data structure 1500 may be stored in any CS in which analytics are implemented, such as personal CS 20 and central CS 10. Data in data structure 1500 enables analytics code to determine by category consumer preferences and purchase patterns, and to identify to the consumer via I/O their preferences, patterns, and previously purchased products.

It should be noted that the PPD may perform additional functions, such as cellular telephone functions and personal digital assistant processing functions.

1. A personal portable device having a size such that it can be carried by a person in one hand, comprising:
computer memory;
a data structure stored by said memory,
input and output structure for inputting data received by said personal portable device into said data structure and outputting data from said data structure out of said personal portable device;
wherein said data structure includes a retailer identification (RID) field and a first consumer identification (CID) field, and said data structure associates said RID field with said first CID field; and
wherein said data structure comprises a first product code (UPC) field and a quantity (Q) field, and said data structure associates said first UPC field with said Q field.

2. The device of claim 1 wherein said data structure comprises a second CID field and a first transaction identification (TID) field, and said data structure associates said second CID field with said first TID field.

3. The device of claim 1 wherein said data structure comprises a second TID field, a price field, and a discount field, and said data structure associates said second TID field, said price field, and said discount field with said first UPC field with said Q field.

4. The device of claim 2 wherein said data structure associates said first CID field with said second CID field.

5. The device of claim 3 wherein said data structure associates said first TID field with said second TID field.

6. The device of claim 1 having RIDs, CIDs, UPCs, and Qs stored in said data structure.

7. The device of claim 1 wherein said data structure further comprises fields for storing incentive offer data, including at least a third CID field for storing CIDs and a second UPC field for storing UPCs.

8. The device of claim 1 further comprising code therein for responding to a prompt from a computer system (CS) including an RID, by outputting to said CS transaction data stored in said data structure in association with said RID.

9. The device of claim 1 further comprising code therein for responding to a prompt from a CS, wherein said prompt includes a RID, by outputting to the prompting CS data identifying incentive offers of which data in said device indicates that terms have been fulfilled and data in said device indicates that no reward has been received.

10. The device of claim 1 further comprising code therein for responding to a prompt from either a personal CS or a central CS including in the prompt a RID by outputting to the prompting CS all transaction data stored in said data structure in association with said RID.

11. The device of claim 1 further comprising code for responding to a prompt from either a personal CS or a central CS by outputting indications of rewards for fulfilled incentive offers.

12. A method for storing data in a PPD, comprising:
prompting of a POS CS, by a PPD, for a RID;
receiving, in said PPD, said RID;
reading, by said POS CS, transaction data for a transaction occurring with said POS CS, said transaction data including UPCs from products being purchased in said transaction; and
transmitting from said POS CS to said PPD said transaction data; and
storing, in said PPD, said transaction data in association with said RID.

13. A method for reading data from a PPD comprising:
transmitting a RID associated with a CS to said PPD;
receiving, in said PPD, said RID;
transmitting from said PPD to said CS transaction data stored in said PPD in association with said RID.

14. A method of making a personal portable device having a size such that it can be carried by a person in one hand, comprising:
providing computer memory;
providing a data structure stored by said computer memory,
providing input and output structure for inputting data received by said personal portable device into said data structure and outputting data from said data structure out of said personal portable device;
wherein said data structure includes a retailer identification (RID) field and a first consumer identification (CID) field, and said data structure associates said RID field with said first CID field; and
wherein said data structure comprises a first product code (UPC) field and a quantity (Q) field, and said data structure associates said first UPC field with said Q field.

15. A network CS comprising said personal portable device of claim 1, and further comprising a central CS and a POS CS, wherein both said central CS and said POS CS have data structures having the same association as said data structure of said personal portable device.

16. A method of using a network CS comprising said personal portable device of claim 1, and further comprising a central CS and a POS CS, wherein both said central CS and said POS CS have data structures having the same association as said data structure of said personal portable device, said method comprising:
storing transaction data in said personal portable device in association with an RID; and
storing said transaction data in said central CS in association with said RID.

17. The method of claim 16 further comprising storing said transaction data in said POS CS having said RID.

18. The method of claim 17 further comprising transmitting incentive offers from said central CS to said personal portable device.

19. The method of claim 18 further comprising determining in said personal portable device, or in an associated personal computer, incentive offers for which terms have been satisfied, and determining a currency amount for said incentive offers.

20. The method of claim 19 further comprising said central CS verifying said currency amount.
